(19) United States
(12) Patent Application Publication
(10) Pub. No.: US 2025/0089453 A1
(43) Pub. Date: Mar. 13, 2025

(54) Display Device

(71) Applicant: LG Display Co., Ltd., Seoul (KR)

(72) Inventors: Yuri Park, Paju-si (KR); Jungmo Cho, Paju-si (KR)

(21) Appl. No.: 18/807,760

(22) Filed: Aug. 16, 2024

(30) Foreign Application Priority Data
Sep. 8, 2023 (KR) 10-2023-0119693

(51) Int. Cl. H10K 59/121; H10K 50/12; H10K 50/18; H10K 59/35; H10K 85/20; H10K 85/30; H10K 85/60

(52) U.S. Cl. CPC H10K 59/121; H10K 50/12; H10K 50/181; H10K 85/20; H10K 85/381; H10K 85/631; H10K 85/654; H10K 85/6572; H10K 59/352; H10K 59/353

(57) ABSTRACT

A display device includes a first active area in which a plurality of first pixels are disposed and which has a first resolution, a second active area in which a plurality of second pixels are disposed and which has a second resolution lower than the first resolution, and multiple light-emitting elements, wherein each of the multiple light-emitting elements includes an electron-blocking layer and a hole-blocking layer, wherein the number of moles of a dopant in at least one of the electron-blocking layer or the hole-blocking layer located in the second active area is greater than the number of moles of a dopant in at least one of the electron-blocking layer or the hole-blocking layer located in the first active area. Accordingly, the difference in luminance between the first active area and the second active area may be reduced.

### CROSS-REFERENCE TO RELATED APPLICATION

This application claims priority from Republic of Korea Patent Application No. 10-2023-0119693, filed on Sep. 8, 2023, which is hereby incorporated by reference for all purposes as if fully set forth herein.

### BACKGROUND

### Field

Embodiments of the present disclosure relate to a display device.

### Description of Related Art

Electroluminescent display devices are divided into inorganic light-emitting display devices and organic light-emitting display devices according to the material of the light-emitting layer.

An active matrix type organic light-emitting display device includes a self-luminous organic light-emitting diode and has various advantages such as fast response speed, high luminous efficiency, high luminance, and wide viewing angle.

In an organic light-emitting display device, an organic light-emitting diode is formed in each pixel. The organic light-emitting display device has fast response speed, high emission efficiency, high luminance, and wide viewing angle, and has also excellent contrast ratio and color gamut because it can express black gradations in complete black.

In modern society, the use of mobile terminals is essential, and multimedia functions for implementing various functions necessary in daily life through mobile terminals are becoming increasingly improved.

For example, smartphones have built-in cameras, and the resolution of the cameras is increasing to the resolution level of existing digital cameras.

However, the front camera of a smartphone limits the size and design of the screen, making it difficult to design the screen wider and more freely.

Accordingly, screen designs including a notch or punch hole have been adopted in smartphones to reduce the space occupied by the camera. However, in this case, the screen size is still limited due to the camera, and thus it is still difficult to achieve a full-screen display.

As used herein, the term “full-screen display” refers to a display device configured such that an image may be displayed on most of the front surface of a mobile terminal.

### SUMMARY

In order to achieve a full-screen display, there has been proposed a method of providing, in a screen of a display panel, an area in which low-resolution pixels are disposed, and disposing a camera and/or various sensors at a position under the display panel, which faces the area in which the low-resolution pixels are disposed.

However, due to the low-resolution pixels of the area in which the low-resolution pixels are disposed, the light-emitting area is reduced, and thus 1.5 times or more current is required to maintain the same luminance.

As the amount of current required increases, a problem arises in that the lifespan decreases, and thus the difference in luminance between the area in which low-resolution pixels are disposed and the area in which high-resolution pixels are disposed increases as time passes, and the boundary of the area in which low-resolution pixels are disposed is clearly recognized.

Accordingly, the inventors of the present disclosure have developed a display device in which the difference in luminance between the area in which low-resolution pixels are disposed and the area in which high-resolution pixels are disposed may be reduced even after long-time operation by increasing the lifespan of only the area in which low-resolution pixels are disposed.

Embodiments of the present disclosure may provide a display device in which the difference in luminance between the area in which low-resolution pixels are disposed and the area in which high-resolution pixels are disposed may be reduced.

Embodiments of the present disclosure may provide a display device including: a first active area in which a plurality of first pixels are disposed and which has a first resolution; a second active area in which a plurality of second pixels are disposed and which has a second resolution lower than the first resolution; and multiple light-emitting elements disposed in each of the plurality of first pixels and the plurality of second pixels, wherein each of the multiple light-emitting elements includes a first electrode layer, an electron-blocking layer on the first electrode layer, a light-emitting layer on the electron-blocking layer, a hole-blocking layer on the light-emitting layer, and a second electrode layer on the hole-blocking layer, wherein at least one of the electron-blocking layer or the hole-blocking layer includes a dopant, and the number of moles of the dopant in at least one of the electron-blocking layer or hole-blocking layer located in the second active area is greater than the number of moles of the dopant in at least one of the electron-blocking layer or hole-blocking layer located in the first active area.

Embodiments of the present disclosure may provide a display device including: a first active area in which a plurality of first pixels are disposed and which has a first resolution; a second active area in which a plurality of second pixels are disposed and which has a second resolution lower than the first resolution; and multiple light-emitting elements disposed in each of the plurality of first pixels and the plurality of second pixels, wherein each of the multiple light-emitting elements includes a first electrode layer, an electron-blocking layer on the first electrode layer, a light-emitting layer on the electron-blocking layer, and a second electrode layer on the light-emitting layer, wherein the electron-blocking layer includes a dopant, and the number of moles of the dopant in the electron-blocking layer located in the second active area is greater than the number of moles of the dopant in the electron-blocking layer located in the first active area.

Embodiments of the present disclosure may provide a display device including: a first active area in which a plurality of first pixels are disposed and which has a first resolution; a second active area in which a plurality of second pixels are disposed and which has a second resolution lower than the first resolution; and multiple light-emitting elements disposed in each of the plurality of first pixels and the plurality of second pixels, wherein each of the multiple light-emitting elements includes a first electrode layer, a light-emitting layer on the first electrode layer, a hole-blocking layer on the light-emitting layer, and a second electrode layer on the hole-blocking layer, wherein the hole-blocking layer includes a dopant, and the number of moles of the dopant in the hole-blocking layer located in the second active area is greater than the number of moles of the dopant in the hole-blocking layer located in the first active area.

Embodiments may provide a display device including a substrate, a plurality of first pixels disposed in a first active area of the substrate, wherein the plurality of first pixels has a first resolution, wherein at least a first pixel includes a light-emitting element including a first electron-blocking layer and a light-emitting layer on the first electron-blocking layer, a plurality of second pixels disposed in a second active area of the substrate, wherein the plurality of second pixels has a second resolution lower than the first resolution, wherein at least a second pixel includes a light-emitting element including a second electron-blocking layer and a light-emitting layer on the second electron-blocking layer, and wherein at least the second electron-blocking layer comprises a dopant, and an amount of the dopant in the second electron-blocking layer located in the second active area is greater than an amount of the dopant in the first electron-blocking layer located in the first active area.

Embodiments may provide a display device including a substrate, a plurality of first pixels disposed in a first active area of the substrate, wherein the plurality of first pixels has a first resolution, wherein at least a first pixel includes a light-emitting element including a light-emitting layer and a first hole-blocking layer on the light-emitting layer, a plurality of second pixels disposed in a second active area of the substrate, wherein the plurality of red pixels has a second resolution lower than the first resolution, wherein at least a second pixel includes a light-emitting element including a light-emitting layer and a second hole-blocking layer on the light-emitting layer, and wherein at least the second hole-blocking layer comprises a dopant, and an amount of the dopant in the second hole-blocking layer located in the second active area is greater than an amount of the dopant in the first hole-blocking layer located in the first active area.

According to embodiments of the present disclosure, it is possible to provide a display device in which the difference in luminance between the area in which low-resolution pixels are disposed and the area in which high-resolution pixels are disposed may be reduced.

In addition, according to embodiments of the present disclosure, it is possible to provide a display device with a long lifespan and low power consumption by using highly efficient low-resolution pixels.

### BRIEF DESCRIPTION OF DRAWINGS

FIG. 1 is a conceptual diagram of a display device according to one embodiment of the present disclosure.

FIG. 2 shows the arrangement of first pixels in the first active area of a display device according to one embodiment of the present disclosure.

FIG. 3 shows the arrangement of second pixels in the second active area of a display device according to one embodiment of the present disclosure.

FIG. 4 is a cross-sectional view schematically showing a display device according to one embodiment of the present disclosure.

FIG. 5 is a cross-sectional view of a light-emitting element according to one embodiment of the present disclosure.

FIG. 6A is a cross-sectional view of a light-emitting element including an N-type dopant in the electron-blocking layer according to one embodiment of the present disclosure.

FIG. 6B is a cross-sectional view of a light-emitting element including a P-type dopant in the hole-blocking layer according to another embodiment of the present disclosure.

FIG. 7A shows the HOMO and LUMO levels of a light-emitting element depending on the presence or absence of an N-type dopant in the electron-blocking layer according to one embodiment of the present disclosure.

FIG. 7B shows the HOMO and LUMO levels of a light-emitting element depending on the presence or absence of a P-type dopant in the hole-blocking layer according to another embodiment of the present disclosure.

FIG. 8 is a flowchart of a method for fabricating a light-emitting element according to one embodiment of the present disclosure.

FIG. 9A is a flowchart of a method for fabricating a light-emitting element according to another embodiment of the present disclosure.

FIG. 9B is a flowchart of a method for fabricating a light-emitting element according to still another embodiment of the present disclosure.

FIG. 10 schematically shows the shapes of masks that may be applied to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to the accompanying drawings.

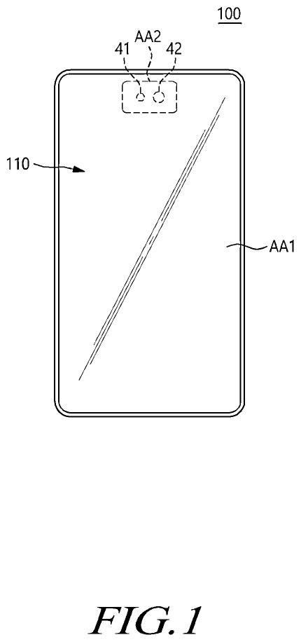

FIG. 1 is a conceptual diagram of a display device 100 according to one embodiment of the present disclosure.

Referring to FIG. 1, the display device 100 may include a display panel 110 and a case.

The front of the display panel 100 may be composed of a display area.

Therefore, a full-screen display becomes possible.

The display area may include a first active area AA1 and a second active area AA2.

Both the first active area AA1 and the second active area AA2 may output images, but they may have different resolutions.

For example, the resolution of a plurality of second pixels PG2 disposed in the second active area AA2 may be lower than the resolution of a plurality of first pixels PG1 disposed in the first active area AA1. The plurality of first pixels PG1 may include at least a first pixel. The plurality of second pixels PG2 may include at least a second pixel.

As the resolution of the plurality of second pixels PG2 disposed in the second active area AA2 is lowered, a sufficient amount of light may be injected into sensors 41 and 42 disposed in the second active area AA2.

However, the present disclosure is not necessarily limited thereto, and the resolution of the first active area AA1 and the resolution of the second active area AA2 may be the same as long as the second active area AA2 has sufficient light transmittance or an appropriate noise compensation algorithm may be implemented.

An example will now be described in which the resolution of the second active area AA2 of the display panel 110 according to one embodiment of the present disclosure is lower than the resolution of the first active area AA1.

The second active area AA2 included in the display panel 110 according to one embodiment of the present disclosure may be an area in which the sensors 41 and 42 are disposed.

The second active area AA2 is an area that overlaps with various sensors and may have a smaller area than the first active area AA1, which outputs most of the image.

The sensors 41 and 42 may include at least one of an image sensor, a proximity sensor, an illumination sensor, a gesture sensor, a motion sensor, a fingerprint recognition sensor, and a biometric sensor.

For example, the first sensor 41 may be an illumination sensor, and the second sensor 42 may be an image sensor for capturing an image or a video, without being limited thereto.

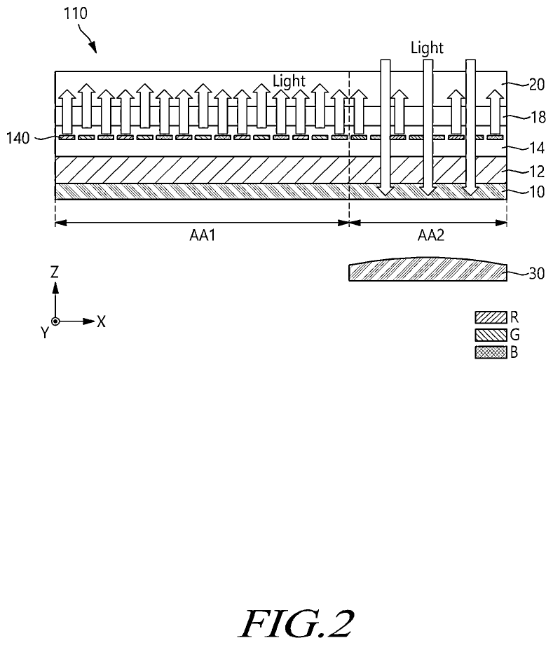

FIG. 2 is a cross-sectional view schematically showing a display device according to one embodiment of the present disclosure.

Referring to FIG. 2, the first active area AA1 and the second active area AA2 may include a pixel array in which pixels that emit light according to pixel data are disposed.

The plurality of first pixels PG1 and the plurality of second pixels PG2 may each represent a pixel array.

In addition, resolution refers to the number of pixels per unit area (pixels per inch (PPI or ppi)), and the number of pixels per unit area of the second active area AA2 may be smaller than the number of pixels per unit area of the first active area AA1 in order to ensure the light transmittance of the second active area AA2.

The pixel array of the first active area AA1 may include a pixel area in which a plurality of pixels with a high number of pixels per unit area are disposed.

The number of pixels per unit area of the first active area AA1 may be 400 ppi or more, without being limited thereto.

The pixel array of the second active area AA2 may include a pixel area in which a plurality of pixel groups with a relatively low number of pixels per unit area are disposed while being spaced apart from each other by light-transmitting areas AG.

The number of pixels per unit area of the second active area AA2 may be 200 ppi or less, without being limited thereto.

In the second active area AA2, external light may pass through the display panel 110 through the light-transmitting areas AG having high light transmittance and be received by a sensor under the display panel 110.

Since both the first active area AA1 and the second active area AA2 include pixels, the input image may be displayed in both the first active area AA1 and the second active area AA2.

Each of the pixels in the first active area AA1 and the second active area AA2 may include sub-pixels having different colors to display the colors of an image.

The sub-pixels may include a red sub-pixel R, a green sub-pixel G, and a blue sub-pixel B.

Although each of the pixels may further include a white sub-pixel, the display device shown in FIG. 2 will be described by way of an example in which each of the pixels includes the red sub-pixel R, the green sub-pixel G, and the blue sub-pixel B.

In addition, each of the sub-pixels may include a pixel circuit and a light-emitting element.

The second active area AA2 may include pixels and a sensor disposed under a screen of the display panel 110.

Although the second active area AA2 may include various types of sensors as described above, the sensor disposed in the display device 100 according to one embodiment of the present disclosure will be described by taking a camera module as an example.

Second pixels PG2 disposed in the second active area AA2 may display an image by writing pixel data of the input image in a display mode.

The camera module may capture an external image in an image capturing mode and output picture or video image data.

A lens of the camera module may face the second active area AA2.

External light is incident on a lens 30 of the camera module through the second active area AA2, and the lens 30 may focus the light on the image sensor.

The camera module may capture the external image in the image capturing mode and output picture or video image data.

Since the second active area AA2 has a relatively low number of pixels per unit area of the pixel array in order to ensure light transmittance, an image quality compensation algorithm may be applied to compensate for the luminance and color coordinates of the pixels in the second active area AA2.

Thus, a full-screen display may be achieved without the display area of the screen being limited by the camera module.

The display panel 110 has a width in the X-axis direction, a length in the Y-axis direction, and a thickness in the Z-axis direction.

The display panel 110 may include a circuit layer 12 disposed on a substrate 10, and a light-emitting element layer 14 disposed on the circuit layer 12.

An encapsulation layer 18 may be disposed on the light-emitting element layer 14, and a cover glass 20 may be disposed on the encapsulation layer 18.

In some cases, in order to improve the outdoor visibility of the display device 100, a polarizing plate may be disposed between the encapsulation layer 18 and the cover glass 20.

The circuit layer 12 may include a pixel circuit connected to lines such as data lines, gate lines, and power lines, a gate driver connected to the gate lines, and the like.

The circuit layer 12 may include circuit elements, such as a transistor composed of a thin film transistor (TFT), and a capacitor, and lines.

The lines and the circuit elements of the circuit layer 12 may include a plurality of dielectric layers, two or more metal layers isolated from each other by the dielectric layer interposed therebetween, and an active layer including a semiconductor material.

The light-emitting element layer 14 may include a light-emitting element 140 driven by the pixel circuit.

The light-emitting element layer 14 may be covered by the encapsulation layer 18.

The encapsulation layer 18 may have a structure in which an organic film and an inorganic film are alternately stacked.

The inorganic film may block the penetration of water or oxygen, and the organic film may planarize the surface of the inorganic film.

When the organic film and the inorganic film are stacked in multiple layers, the movement path of water or oxygen becomes longer than that in a single layer, thereby effectively blocking the penetration of water and oxygen affecting the light-emitting element layer 14.

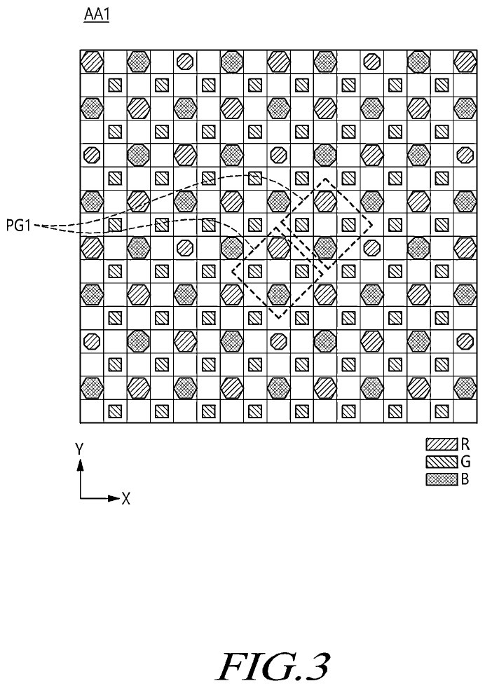

FIG. 3 shows the arrangement of first pixels PG1 in the first active area AA1 of the display device 100 according to one embodiment of the present disclosure.

Referring to FIG. 3, the first active area AA1 may include first pixels PG1 arranged in a matrix form.

Each of the plurality of first pixels PG1 may be composed of a single unit pixel including a red sub-pixel R, a green sub-pixel G, and a blue sub-pixel B.

Each of the plurality of first pixels PG1 may further include a white sub-pixel.

In addition, two sub-pixels may be configured as one pixel using a sub-pixel rendering algorithm.

As an example, the first pixel PG1 may include a red sub-pixel R and a green sub-pixel G.

As another example, the first pixel PG1 may be configured to include a blue sub-pixel B and a green sub-pixel G.

Insufficient color representation in each of the first pixels PG1 may be compensated for by the average value of the corresponding color data of neighboring pixels through a sub-pixel rendering algorithm.

Although FIG. 3 illustrates that the arrangement of sub-pixels in which the red sub-pixel R, the green sub-pixel G, the blue sub-pixel B, and the green sub-pixel G are arranged in zigzag in the X-axis direction, the arrangement of sub-pixels is not limited thereto.

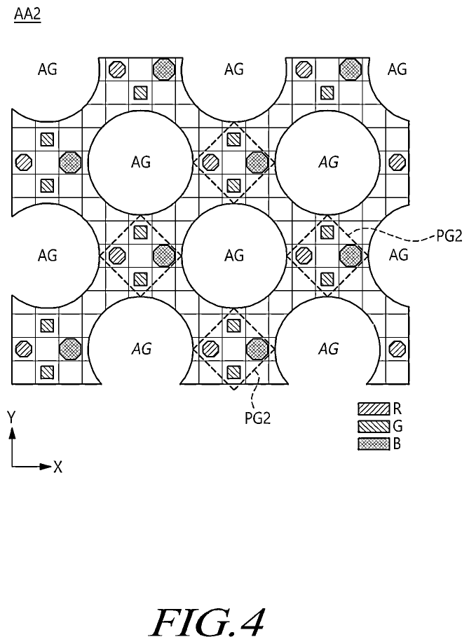

FIG. 4 shows the arrangement of the second pixels PG2 in the second active area AA2 of the display device 100 according to one embodiment of the present disclosure.

Referring to FIG. 4, a plurality of light-transmitting areas (AG) may exist in the second active area AA2. Each of the plurality of light-transmitting areas AG may be disposed between the plurality of second pixels PG2.

The light transmitting area AG may include metal-free transparent media having a high light transmittance so that light may be incident while light loss is reduced or minimized.

The light-transmitting area AG may be composed of transparent dielectric materials without including metal lines or pixels.

Although the shape of the light transmitting area AG is illustrated as being circular, the shape is not limited thereto.

For example, the light-transmitting area AG may be designed in various shapes such as circular, oval, or polygonal shapes.

Details about the second pixels PG2 may be substantially the same as those about the first pixels PG1 described above with respect to FIG. 3, except for details about the dopant, which will be described later.

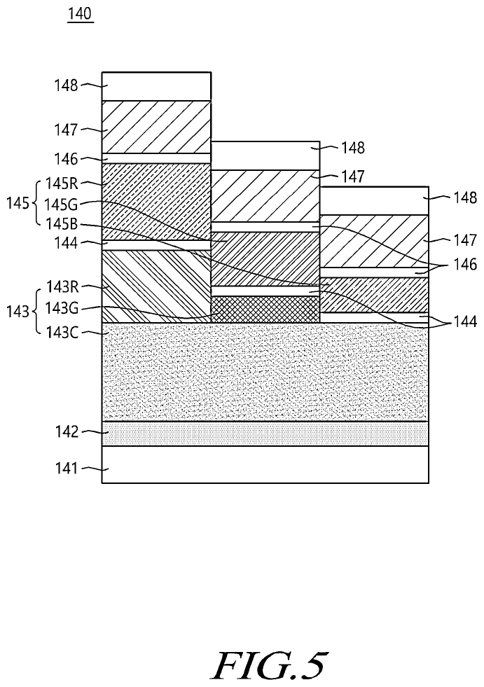

FIG. 5 is a cross-sectional view of a light-emitting element 140 according to one embodiment of the present disclosure.

Referring to FIG. 5, the light-emitting element 140 according to one embodiment includes a red sub-pixel R, a green sub-pixel G, and a blue sub-pixel B, which emit different colors, on the substrate 10.

The light-emitting element 140 may include a first electrode layer 141 disposed on the substrate 10, a second electrode layer 148 disposed to face the first electrode layer 141, and a light-emitting layer 145 formed between the first electrode layer 141 and the second electrode layer 148.

The first electrode layer 141 may be an anode and the second electrode layer 148 may be a cathode, but embodiments of the present disclosure are not limited thereto.

For example, in the case of an inverted type, the first electrode layer 141 may be a cathode and the second electrode layer 148 may be an anode.

However, in the embodiments described later, the description will focus on the configuration in which the first electrode layer 141 of the light-emitting element 140 is an anode and the second electrode layer 148 is a cathode.

The first electrode layer 141 may be electrically connected to any one of a source and drain in a transistor including the source, the drain, a gate, and an active layer via a contact hole formed in a dielectric layer.

The first electrode layer 141 may be composed of a material having a relatively high work function.

The first electrode layer 141 may be composed of, for example, a transparent conductive oxide such as indium tin oxide (ITO), indium zinc oxide (IZO), zinc oxide (ZnO), Al-doped zinc oxide (AZO), indium oxide (In₂O₃), or tin oxide (SnO₂), without being limited thereto.

The second electrode layer 148 may be composed of a metal, an alloy, an electrically conductive compound, or a mixture of two or more thereof, which has a relatively low work function.

As an example, a transmissive electrode may be obtained by forming a thin film of lithium (Li), magnesium (Mg), aluminum (Al), aluminum-lithium (Al—Li), calcium (Ca), magnesium-indium (Mg—In), magnesium-silver (Mg—Ag), or the like.

Meanwhile, various modifications, such as forming a transmissive electrode using ITO or IZO to obtain a top emitting device, may be made to the embodiments of the present disclosure.

A capping layer (not shown) may be disposed on the second electrode layer 148 to improve optical properties and maximize luminous efficiency.

As an example, the capping layer may be composed of a metal oxide layer, a metal nitride layer, or a metal oxynitride layer.

For example, the capping layer may be composed of MoOₓ (x=2 to 4), Al₂O₃, Sb₂O₃, BaO, CdO, CaO, Ce₂O₃, CoO, Cu₂O, DyO, GdO, HfO₂, La₂O₃, Li₂O, MgO, NbO, NiO, Nd₂O₃, PdO, Sm₂O₃, ScO, SiO₂, SrO, Ta₂O₃, TiO, WO₃, VO₂, YbO, Y₂O₃, ZnO, ZrO, AlN, BN, NbN, SiN, TaN, TiN, VN, YbN, ZrN, SiON, AlON, or a mixture of two or more thereof, without being limited thereto.

The light-emitting layer 145 may include a red organic emission layer 145R disposed in the red sub-pixel R, a green organic emission layer 145G disposed in the green sub-pixel G, and a blue organic emission layer 145B disposed in the blue sub-pixel B.

In this case, the size of the wavelength of the emitted light is larger in the order of the red organic emission layer 145R, the green organic emission layer 145G, and the blue organic emission layer 145B.

The red organic emission layer 145R may include a red host and a red dopant.

As the red host, Alq3, CBP, PVK, AND, TCTA, TPBI, TBADN, E3, DSA, or a mixture of two or more thereof may be used, without being limited thereto.

As the red dopant, a compound including PtOEP, Ir(piq)₃, Btp₂Ir(acac), Ir(2-phq)₂(acac), Ir (2-phq)₃, Ir (flq)₂(acac), Ir(fliq)₂(acac), DCM or DCJTB may be used, without being limited thereto.

The green organic emission layer 145G may include a green host and a green dopant.

The green host used may be Alq3, CBP, PVK, AND, TCTA, TPBI, TBADN, E3, DSA, or a mixture of two or more thereof, without being limited thereto.

The green dopant used may be tris(2-phenylpyridine)iridium (Ir(ppy)₃), bis(2-phenylpyridine) (acetylacetonato)iridium(III) (Ir(ppy)₂(acac)), tris(2-(4-tolyl)phenylpiridine)iridium (Ir(mppy)₃), 10-(2-benzothiazolyl)-1,1,7,7-tetramethyl-2,3,6,7-tetrahydro-1H,5H,11H-[1]benzopyrano [6,7,8-ij]-quinolizinll-one (C545T), or the like, without being limited thereto.

The blue organic emission layer 145B may include a blue host and a blue dopant.

The blue host used may be Alq₃, 4,4′-N,N′-dicabazole-biphenyl (CBP), poly(n-vinylcarbazole (PVK), 9,10-di(naphthalene-2-yl) anthracene (AND), TCTA, 1,3,5-tris(N-phenylbenzimidazole-2-yl)benzene (TPBI), 3-tert-butyl-9,10-di(naphth-2-yl)anthracene (TBADN), E3, distyrylarylene (DSA), or a mixture of two or more thereof, without being limited thereto.

The blue dopant used may be a compound including F₂Irpic, (F₂ppy)₂Ir(tmd), Ir(dfppz)₃, ter-fluorene, 4,4′-bis(4-diphenylaminostyryl)biphenyl (DPAVBi), TBPe, or the like, without being limited thereto.

The light-emitting element 140 may include a hole transport layer 143 disposed between the first electrode layer 141 and the light-emitting layer 145.

The hole transport layer 143 may include a common hole transport layer 143C disposed on the hole injection layer 142.

The hole transport layer 143 may include a light-emitting auxiliary layer disposed between the hole transport layer 143 and the common hole transport layer 143C.

The light-emitting auxiliary layer may include a red light-emitting auxiliary layer 143R, a green light-emitting auxiliary layer 143G, and a blue light-emitting auxiliary layer (not shown), which are disposed on the hole transport layer 143C.

For example, the light-emitting auxiliary layers may serve to transport holes and may be composed of hole transport material. The light-emitting auxiliary layers may be composed of the same material or compound or may be composed of different materials or compounds.

As an example, the hole transport layer 143, the common hole transport layer 143C, the red light-emitting auxiliary layer 143R, the green light-emitting auxiliary layer 143G, and the blue light-emitting auxiliary layer (not shown) may include materials containing tertiary amine or fluorine-containing tertiary amine, without being limited thereto.

The light-emitting element 140 may include a hole injection layer 142 disposed on the first electrode layer 141, a hole transport layer 143 disposed on the hole injection layer 142, a light-emitting layer 145 disposed on the hole transport layer 143, and an electron transport layer 147 disposed on the light-emitting layer 145, without being limited thereto.

When voltage is applied to the first electrode layer 141 and the second electrode layer 148 of the light-emitting element 140, holes that passed through the hole transport layer 143 and electrons that passed through the electron transport layer 147 may move to the light-emitting layer 145 to form excitons, and visible light may be emitted from the light-emitting layer 145.

The light-emitting element 140 may include an electron-blocking layer 144 between the hole transport layer 143 and the light-emitting layer 145.

However, the present disclosure is not necessarily limited thereto, and the light-emitting element 140 may not include the electron-blocking layer 144.

The electron-blocking layer 144 may include at least one of tris(phenylpyrazole)iridium, 9,9-bis[4-(N,N-bis-biphenyl-4-ylamino)phenyl]-9H-fluorene (BPAPF), bis[4-(p,p-ditolylamino)phenyl]diphenylsilane, 4,4′-bis[N-(1-napthyl)-N-phenyl-amino]biphenyl (NPD), N,N′-dicarbazolyl-3,5-benzene (mCP), and bis[4-(N,N-diethylamino)-2-methylphenyl](4-methylphenyl)methane (MPMP), or a combination of two or more thereof, without being limited thereto.

In addition, the electron-blocking layer 144 may include an inorganic compound. As an example, the electron-blocking layer 144 may include at least one of halide compounds, such as LiF, NaF, KF, RbF, CsF, FrF, MgF₂, CaF₂, SrF₂, BaF₂, LiCl, NaCl, KCl, RbCl, CsCl, and FrCl, and oxides such as Li₂O, Li₂O₂, Na₂O, K₂O, Rb₂O, Rb₂O₂, Cs₂O, Cs₂O₂, LiAlO₂, LiBO₂, LiTaO₃, LiNbO₃, LiWO₄, Li₂CO, NaWO₄, KAlO₂, K2SiO₃, B₂O₅, Al₂O₃, and SiO₂, or a combination of two or more thereof, without being limited thereto.

The electron-blocking layer 144 may serve as a buffer layer that blocks direct contact between the hole transport layer 143 and the light-emitting layer 145, and may serve to prevent electrons from easily flowing into the hole transport layer 143.

In other words, the electron-blocking layer 144 may improve the efficiency and lifespan of the light-emitting element 140 by controlling the electron injection, movement, and combination with holes.

The electron transport layer 147 may be disposed on the light-emitting layer 145.

The electron transport layer 147 may control the movement speed of electrons so that electrons and holes may meet in the light-emitting layer 145 and emit light.

The electron transport layer 147 may include a material through which the speed of electron movement is several times higher than that through other materials.

For example, the electron transport layer 147 may include at least one of tris(8-hydroxyquinolino)aluminum (Alq₃), PBD, TAZ, spiro-PBD, BAlq, and SAlq, or a combination of two or more thereof, without being limited thereto.

An electron injection layer (not shown) may be disposed on the electron transport layer 147.

The electron injection layer (not shown) may serve to transfer electrons introduced from the second electrode layer 148 to the electron transport layer 147.

The light-emitting element 140 may include a hole-blocking layer 146 between the light-emitting layer 145 and the electron transport layer 147.

However, the present disclosure is not necessarily limited thereto, and the light-emitting element 140 may not include the hole-blocking layer 146.

The hole-blocking layer 146 may serve as a buffer layer that blocks direct contact between the electron transport layer 147 and the light-emitting layer 145 and may serve to prevent holes from easily flowing into the electron transport layer 147.

The hole-blocking layer 146 may improve the efficiency and lifespan of the light-emitting element 140 by controlling the hole injection, movement, and combination with electrons.

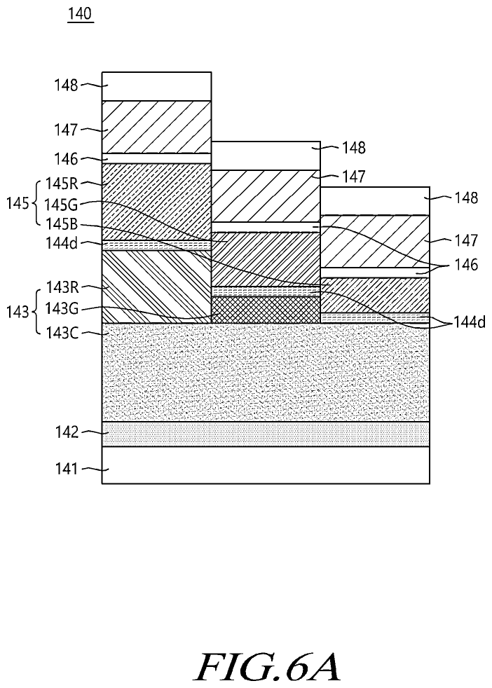

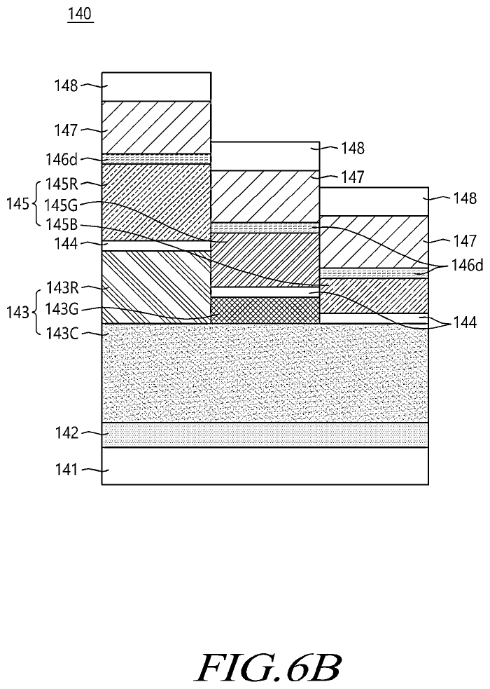

FIG. 6A is a cross-sectional view of a light-emitting element including an N-type dopant in the electron-blocking layer according to one embodiment of the present disclosure.

Referring to FIG. 6A, the light-emitting element 140 may include an electron-blocking layer 144d including an N-type dopant. In one embodiment, the light-emitting element 140 is included in a first pixel of a plurality of first pixels in the first active area AA1 and includes a first electron-blocking layer and a light-emitting layer on the first electron-blocking layer. In one embodiment, the light-emitting element 140 is included in a second pixel of a plurality of second pixels in the second active area AA2 and includes a second electron-blocking layer and a light-emitting layer on the second electron-blocking layer.

In one embodiment, an amount of N-type dopant in at least the second electron-blocking layer is greater than an amount of N-type dopant in at least the first electron-blocking layer. In one embodiment, the amount is the number of moles of the dopant, and the number of moles of the N-type dopant in at least one of the electron-blocking layers 144d located in the second active area may be greater than the number of moles of the N-type dopant in at least one of the electron-blocking layers 144d located in the first active area. However, it is appreciated that in other embodiments, the amount may refer to the weight of the dopant, the volume of the dopant, and the like in the electron-blocking layer.

The N-type dopant in the electron-blocking layer 144d may be at least one of the following compounds, without being limited thereto:

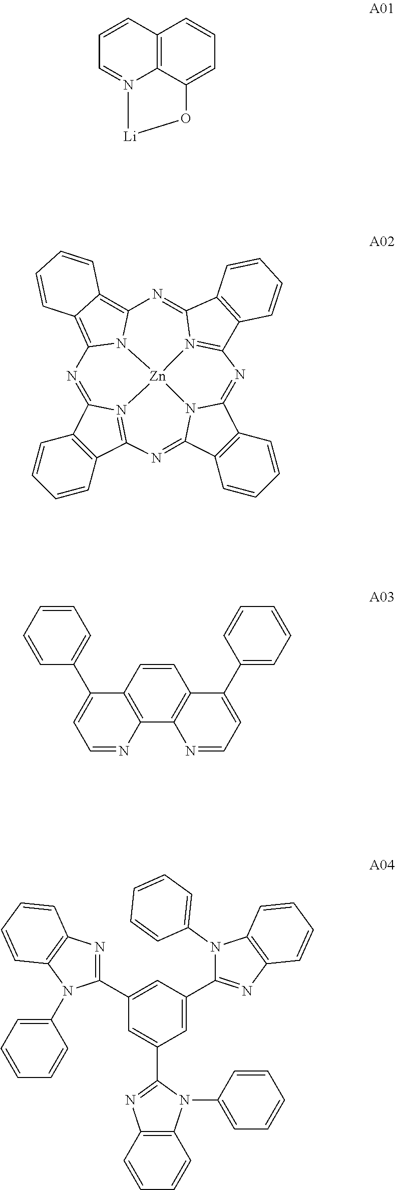

In one embodiment, the light-emitting element 140 of the first pixel or second pixel includes a first electrode layer 141, a common hole transport layer 143C on the first electrode layer 141, a red light-emitting auxiliary layer 143R on a first portion of the common hole transport layer 143C, a green light-emitting auxiliary layer 143G on a second portion of the common hole transport layer 143C, the second electron-blocking layer 144d on the red light-emitting auxiliary layer 143R, the green light-emitting auxiliary layer 143G, and a third portion of the common hole transport layer 143C.

As the number of moles of the N-type dopant in the electron-blocking layer 144d increases, the LUMO energy level of the electron-blocking layer 144d may be lowered.

In addition, as the number of moles of the N-type dopant in the electron-blocking layer 144d increases, the recombination zone where holes and electrons combine increases, thereby reducing exciton quenching, thus increasing the lifespan.

When the number of moles of the N-type dopant in the electron-blocking layer 144d is low, the recombination zone is biased toward the electron-blocking layer 144d.

On the other hand, when the number of moles of the N-type dopant in the electron-blocking layer 144d is high, the LUMO energy level of the electron-blocking layer 144d is lowered, and thus the recombination zone moves toward the hole-blocking layer 146 and moves to the center of the light-emitting layer 145, and hole mobility increases, thereby increasing the lifespan.

Thus, when the number of moles of the N-type dopant in at least one of the electron-blocking layers 144d located in the second active area is greater than the number of moles of the N-type dopant in at least one of the electron-blocking layers 144d located in the first active area, the lifespan of the light-emitting element 140 located in the second active area AA2 increases.

In addition, when a P-type dopant is applied to the hole transport layer 143, gas may be released by external heat when the light-emitting element 140 is driven for a long period of time, and the released gas may react with the P-type dopant in the hole transport layer 143, resulting in denaturation of the material.

Denaturation of the material may affect the HOMO energy level of the hole transport layer 143, causing degradation of the light-emitting element 140.

When an N-type dopant is applied to the electron-blocking layer 144d instead of the hole transport layer 143, thermal degradation of the light-emitting element 140 may be prevented.

In addition, when the number of moles of the N-type dopant in at least one of the electron-blocking layers 144d located in the second active area is greater than the number of moles of the N-type dopant in at least one of the electron-blocking layers 144d located in the first active area, the difference in luminance between the second active area AA2 and the first active area AA1 decreases.

At the same current, the lifespan of the light-emitting element 140 in the second active area AA2 may increase by at least 1.5 times compared to that of the light-emitting element 140 in the first active area AA1.

If the lifespan of the light-emitting element 140 located in the second active area AA2 increases, the difference in luminance between the second active area AA2 and the first active area AA1 may decrease even when driven for a long time.

As another example, only the electron-blocking layer 144d located in the second active area may include the N-type dopant, and the electron-blocking layer 144 located in the first active area may not include the N-type dopant.

When only the electron-blocking layer 144d located in the second active area includes the N-type dopant, the difference in luminance between the second active area AA2 and the first active area AA1 may become smaller.

As another example, the number of moles of the N-type dopant in at least one of the electron-blocking layers 144d located in the second active area may be greater than the number of moles of the N-type dopant in at least one of the electron-blocking layers 144d located in the first active area, while the number of moles of the N-type dopant in at least one of the electron-blocking layers 144d located in the second active area may be equal to or greater than the number of moles of the electron-blocking layer 144d located in the second active area.

If the number of moles of the dopant in at least one of the electron-blocking layers 144d located in the second active area is greater than the number of moles of the electron-blocking layer 144d located in the second active area, the energy gap between the LUMO of the light-emitting layer 145 and the LUMO of the electron-blocking layer 144d becomes 0.7 eV or less, making it easier for electrons to flow into the hole transport layer 143.

In other words, if the energy gap between the LUMO of the light-emitting layer 145 and the LUMO of the electron-blocking layer 144d becomes 0.7 eV or less, the function of the electron-blocking layer 144d may be weakened.

In the present specification, the number of moles of the electron-blocking layer 144d refers to the sum of the number of moles of the portion that is the N-type dopant and the number of moles of the portion that is not the N-type dopant in the material constituting the electron-blocking layer 144d.

FIG. 6B is a cross-sectional view of a light-emitting element 140 including a P-type dopant in the hole-blocking layer according to another embodiment of the present disclosure.

Referring to FIG. 6B, the light-emitting element 140 may include a hole-blocking layer 146d including a P-type dopant. In one embodiment, the light-emitting element 140 is included in a first pixel of a plurality of first pixels in the first active area AA1 and includes a light-emitting layer, and a first hole-blocking layer on the light-emitting layer. In one embodiment, the light-emitting element 140 is included in a second pixel of a plurality of second pixels in the second active area AA2 and includes a light-emitting layer, and a second hole-blocking layer on the light-emitting layer.

In one embodiment, an amount of P-type dopant in at least the second hole-blocking layer is greater than an amount of P-type dopant in at least the first hole-blocking layer. In one embodiment, the amount is the number of moles of the dopant, and the number of moles of the P-type dopant in at least one of the hole-blocking layers 146d located in the second active area may be greater than the number of moles of the P-type dopant in at least one of the hole-blocking layers 146d located in the first active area. However, it is appreciated that in other embodiments, the amount may refer to the weight of the dopant, the volume of the dopant, and the like in the hole-blocking layer.

The P-type dopant in the hole-blocking layer 146d may be at least one of the following compounds, without being limited thereto:

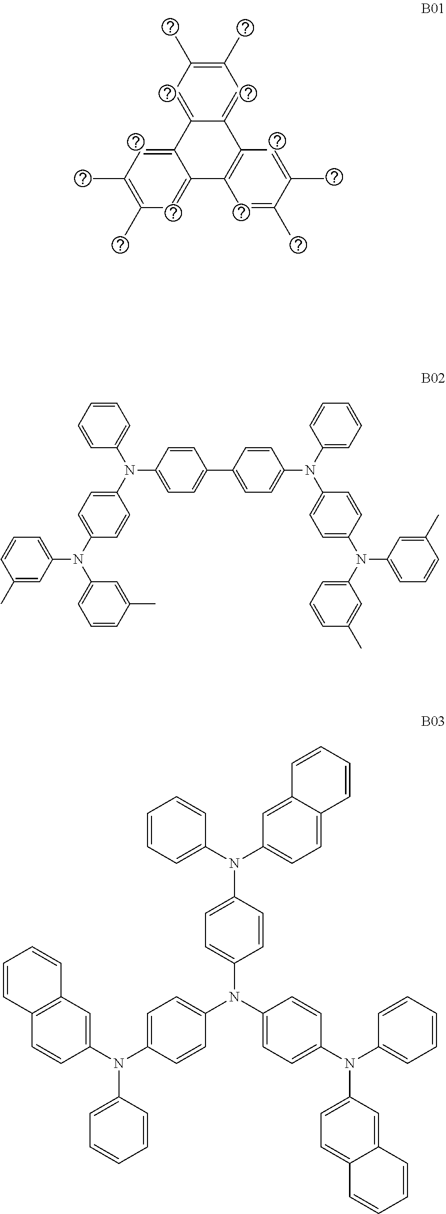

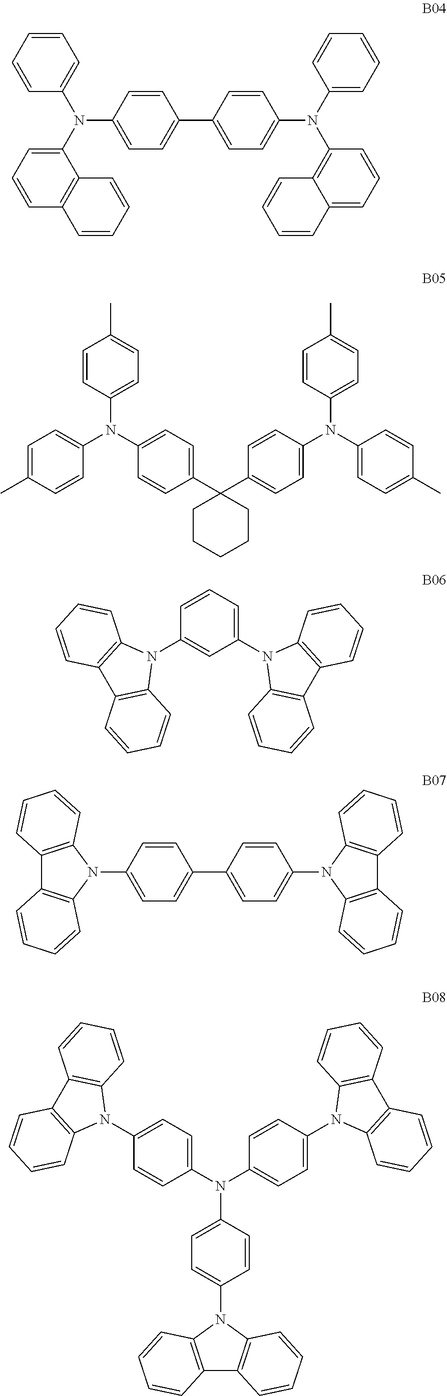

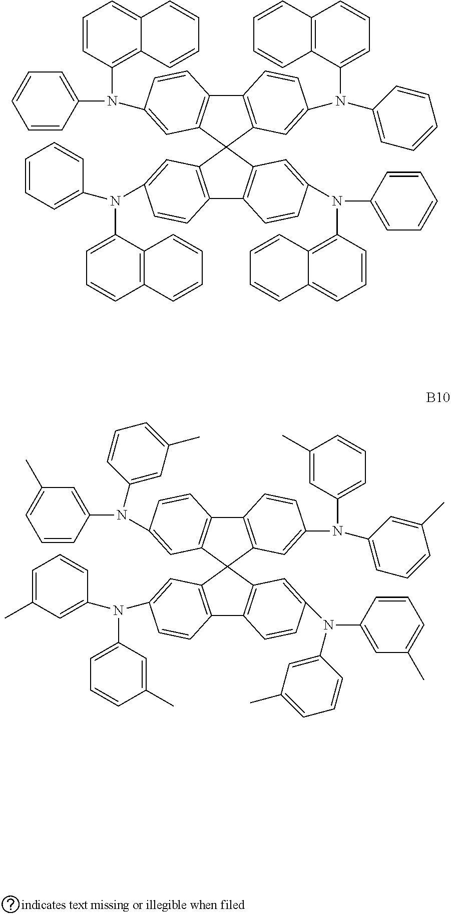

In one embodiment, the light-emitting element 140 of the first pixel or second pixel includes a first electrode layer 141, a common hole transport layer 143C on the first electrode layer 141, a red light-emitting auxiliary layer 143R on a first portion of the common hole transport layer 143C, a green light-emitting auxiliary layer 143G on a second portion of the common hole transport layer 143C, the light-emitting layer 145, the second hole-blocking layer 146d on the light-emitting layer 145, and an electron transport layer 147.

As the number of moles of the P-type dopant in the hole-blocking layer 146d increases, the energy level of the HOMO of the hole-blocking layer 146d may be lowered.

In addition, when the number of moles of the P-type dopant in the hole-blocking layer 146d increases, the movement of holes from the light-emitting layer 145 to the hole-blocking layer 146d is blocked, and thus a recombination zone is formed in the middle of the light-emitting layer 145, thus increasing the area of the recombination zone.

Thus, as the area of the recombination zone increases, the lifespan increases.

Therefore, when the number of moles of the P-type dopant in at least one of the hole-blocking layers 146d located in the second active area is greater than the number of moles of the P-type dopant in at least one of the hole-blocking layers 146d located in the first active area, the lifespan of the light-emitting element 140 located in the second active area AA2 increases.

In addition, when the number of moles of the P-type dopant in at least one of the hole-blocking layers 146d located in the second active area is greater than the number of moles of the P-type dopant in at least one of the hole-blocking layers 146d located in the first active area, the difference in luminance between the second active area AA2 and the first active area AA1 becomes smaller.

At the same current, the lifespan of the light-emitting element 140 in the second active area AA2 may increase by at least 1.5 times compared to that of the light-emitting element 140 in the first active area AA1.

As the lifespan of the light-emitting element 140 located in the second active area AA2 increases, the difference in luminance between the second active area AA2 and the first active area AA1 may decrease even when driven for a long time.

As another example, only the hole-blocking layer 146d located in the second active area may include the P-type dopant, and the hole-blocking layer 146 located in the first active area may not include the P-type dopant.

When only the hole-blocking layer 146d located in the second active area includes the P-type dopant, the difference in luminance between the second active area AA2 and the first active area AA1 may become smaller.

Meanwhile, in another embodiment, the light-emitting element 140 located in the second active area AA2 may have a tandem structure. Specifically, the red organic emission layer 145R may include a first red sub-organic emission layer (not shown) and a second red sub-organic emission layer (not shown), and a first charge generation layer (not shown) may be disposed between the first red sub-organic emission layer (not shown) and the second red sub-organic emission layer (not shown). In addition, the green organic emission layer 145G may include a first green sub-organic emission layer (not shown) and a second green sub-organic emission layer (not shown), and a second charge generation layer (not shown) may be disposed between the first green sub-organic emission layer (not shown) and the second green sub-organic emission layer (not shown). In addition, the blue organic emission layer 145B may include a first blue sub-organic emission layer (not shown) and a second blue sub-organic emission layer (not shown), and a third charge generation layer (not shown) may be disposed between the first blue sub-organic emission layer (not shown) and the second blue sub-organic emission layer (not shown). When the light-emitting element 140 located in the second active area AA2 has the tandem structure as described above, the efficiency of the light-emitting element 140 located in the second active area AA2 may be improved, and thus the difference in luminance between the second active area AA2 and the first active area AA1 may be further reduced.

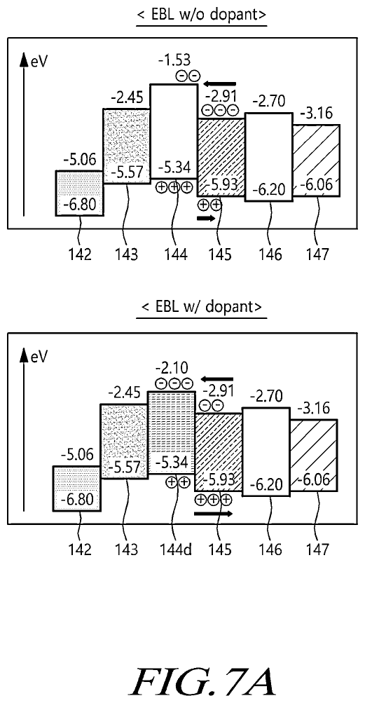

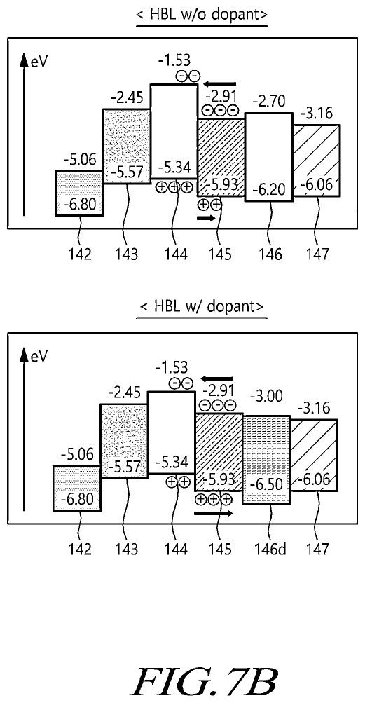

FIG. 7A shows the HOMO and LUMO levels of the light-emitting element 140 depending on the presence or absence of an N-type dopant in the electron-blocking layer 144d according to one embodiment of the present specification.

In the present disclosure, the HOMO and LUMO levels were measured using cyclic voltammetry (CV).

Referring to FIG. 7A, it can be seen that the LUMO of the electron-blocking layer 144d is lowered when the electron-blocking layer 144d includes the N-type dopant (<EBL w/dopant>) compared to when the electron-blocking layer 144 does not include the N-type dopant (<EBL w/o dopant>).

As the LUMO of the electron-blocking layer 144d is lowered from −1.53 eV to −2.10 eV, the energy gap between the light-emitting layer 145 and the electron-blocking layer 144d becomes smaller, and thus the recombination zone moves toward the hole-blocking layer 146 and moves to the center of the light-emitting layer 145, and the hole mobility increases, thus increasing the lifespan of the light-emitting element 140.

FIG. 7B shows the HOMO and LUMO levels of the light-emitting element 140 depending on the presence or absence of a P-type dopant in the hole-blocking layer 146d according to another embodiment of the present disclosure.

Referring to FIG. 7B, it can be seen that the HOMO of the hole-blocking layer 146d is lowered when the hole-blocking layer 146d includes the P-type dopant (<HBL w/dopant>) compared to when the hole-blocking layer 146 does not include the P-type dopant (<HBL w/o dopant>).

As the HOMO of the hole-blocking layer 146d is lowered from −6.20 eV to −6.50 eV, the movement of holes from the light-emitting layer 145 to the hole-blocking layer 146d is blocked, and thus a recombination zone is formed in the middle of the light-emitting layer 145, thus increasing the area of the recombination zone. Accordingly, the lifespan of the light-emitting element 140 increases.

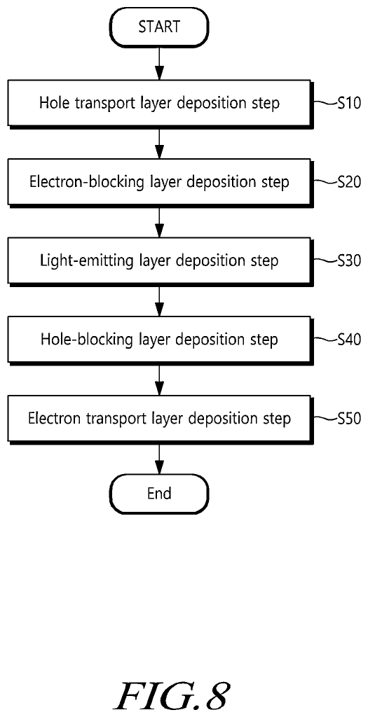

FIG. 8 is a flowchart of a method for fabricating a light-emitting element according to one embodiment of the present disclosure.

Referring to FIG. 8, the method for fabricating a light-emitting element according to one embodiment of the present disclosure includes a hole transport layer deposition step S10, an electron-blocking layer deposition step S20, a light-emitting layer deposition step S30, a hole-blocking layer deposition step S40, and an electron transport layer deposition step S50.

In the method for fabricating a light-emitting element according to embodiments of the present disclosure, details regarding the hole transport layer, the electron-blocking layer, the light-emitting layer, the hole-blocking layer, and the electron transport layer are the same as those regarding the hole transport layer 143, electron-blocking layer 144, light-emitting layer 145, hole-blocking layer 146, and electron transport layer 147 described above with respect to the light-emitting element 140 according to one embodiment, unless otherwise specified.

The hole transport layer deposition step S10 is a step of depositing the hole transport layer using an open metal mask (OMM).

The electron-blocking layer deposition step S20 is a step of depositing the electron-blocking layer using an open metal mask (OMM).

The light-emitting layer deposition step S30 is a step of depositing the light-emitting layer using a fine metal mask (FMM).

The hole-blocking layer deposition step S40 is a step of depositing the hole-blocking layer using an open metal mask (OMM).

The electron transport layer deposition step S50 is a step of depositing the electron transport layer using an open metal mask (OMM).

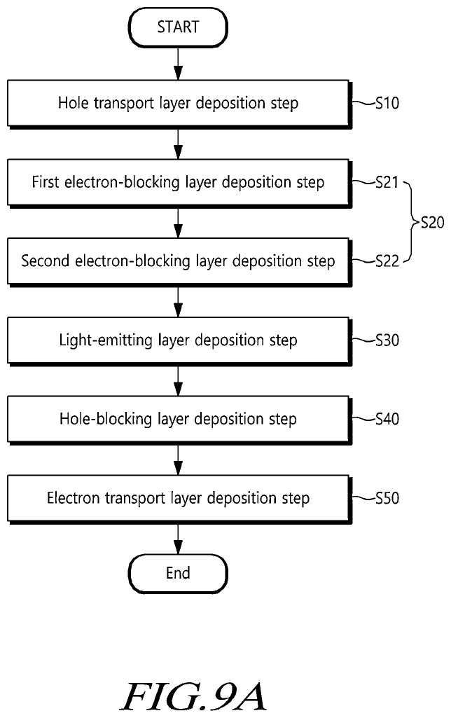

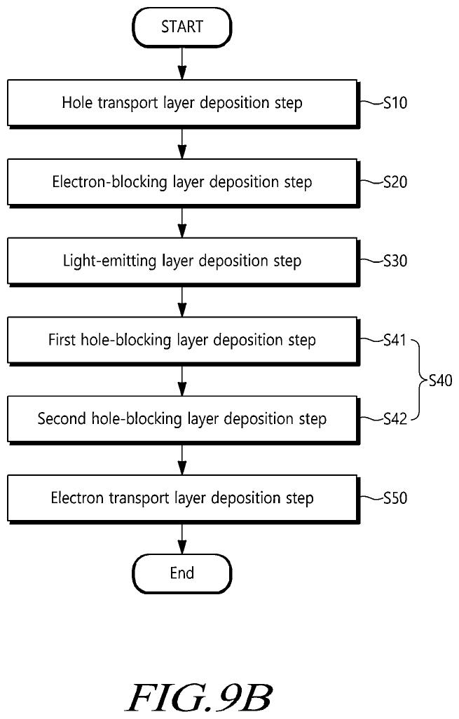

FIG. 9A is a flowchart of a method for fabricating a light-emitting element according to another embodiment of the present disclosure.

In the method for fabricating a light-emitting element according to embodiments of the present disclosure, details regarding the hole transport layer, the electron-blocking layer, the light-emitting layer, the hole-blocking layer, and the electron transport layer are the same as those regarding the hole transport layer 143, electron-blocking layer 144, 144d, light-emitting layer 145, hole-blocking layer 146, and electron transport layer 147 described above with respect to the light-emitting element 140 according to one embodiment, unless otherwise specified.

Referring to FIG. 9A, the electron-blocking layer deposition step S20 may include a first electron-blocking layer deposition step S21 and a second electron-blocking layer deposition step S22.

As an example, the first electron-blocking layer deposition step S21 may be a step of depositing the electron-blocking layer in the first active area AA1, and the second electron-blocking layer deposition step S22 may be a step of depositing the electron-blocking layer in the second active area AA2.

However, the present disclosure is not necessarily limited thereto, and the first electron-blocking layer deposition step S21 may be a step of depositing the electron-blocking layer in the second active area AA2, and the second electron-blocking layer deposition step S22 may be a step of depositing the electron-blocking layer in the first active area AA1.

In order to fabricate the display device 100 in which the number of moles of the N-type dopant in at least one of the electron-blocking layers 144d located in the second active area is greater than the number of moles of the N-type dopant in at least one of the electron-blocking layers 144d located in the first active area, one more mask is required than the number of masks used in the light-emitting element fabrication method described with respect to FIG. 8.

FIG. 9B is a flow chart of a method for fabricating a light-emitting element according to another embodiment of the present disclosure.

In the method for fabricating a light-emitting element according to embodiments of the present disclosure, details regarding the hole transport layer, the electron-blocking layer, the light-emitting layer, the hole-blocking layer, and the electron transport layer are the same as those regarding the hole transport layer 143, electron-blocking layer 144, light-emitting layer 145, hole-blocking layer 146d, and electron transport layer 147 described above with respect to the light-emitting element 140 according to one embodiment, unless otherwise specified.

Referring to FIG. 9B, the hole-blocking layer deposition step S40 may include a first hole-blocking layer deposition step S41 and a second hole-blocking layer deposition step S42.

As an example, the first hole-blocking layer deposition step S41 may be a step of depositing the hole-blocking layer in the first active area AA1, and the second hole-blocking layer deposition step S42 may be a step of depositing the hole-blocking layer in the second active area AA2.

However, the present disclosure is not necessarily limited to this, and the first hole-blocking layer deposition step S41 may be a step of depositing the hole-blocking layer in the second active area AA2, and the second hole-blocking layer deposition step S42 may be a step of depositing the hole-blocking layer in the first active area AA1.

In order to fabricate the display device 100 in which the number of moles of the P-type dopant in at least one of the hole-blocking layers 144d located in the second active area is greater than the number of moles of the P-type dopant in at least one of the hole-blocking layers 144d located in the first active area, one more mask is required than the number of masks used in the light-emitting element fabrication method described with respect to FIG. 8.

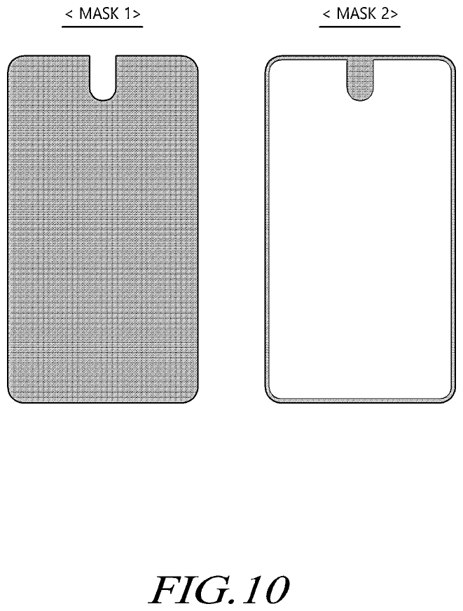

FIG. 10 schematically shows the shapes of masks that may be applied to embodiments of the present disclosure.

Referring to FIG. 10, <MASK 1> may be a mask used in the step of depositing the electron-blocking layer or the hole-blocking layer in the first active area AA1.

<MASK 2> may be a mask used in the step of depositing the electron-blocking layer or the hole-blocking layer in the second active area AA2.

Hereinafter, embodiments of the present disclosure will be described in detail by way of experimental examples, but the present disclosure is not limited to the following examples.

Electroluminescent (EL) characteristics were measured by applying a forward bias DC voltage of 4.5V to blue light-emitting elements, and the results of the measurement are shown in Table 1 below. In Table 1 below, Comparative Example 1 is one in which the electron-blocking layer of the blue light-emitting element was not doped with the N-type dopant, and Example 1 is one in which the electron-blocking layer of the blue light-emitting element was doped with the N-type dopant.

TABLE 1

| | Luminous efficiency | |
|---|---|---|
| | (cd/A) | T95 lifespan (h) |
| Comparative Example 1 | 6.1 | 450 |
| Example 1 | 5.8 | 600 |

From the results in Table 1 above, it can be seen that the lifespan increased from 450 hours to 600 hours in the case in which the electron-blocking layer of the blue light-emitting element was doped with the N-type dopant compared to the case in which the electron-blocking layer was not doped with the N-type dopant.

In other words, it can be seen that the efficiency decreased from 6.1 cd/A to 5.8 cd/A, which is 95% of the efficiency of Comparative Example 1, but the lifespan increased from 450 hours to 600 hours, which is 133% of the lifespan of Comparative Example 1.

For Comparative Example 1 and Example 1 in Table 1 above, the difference in luminance between the first active area and the second active area was measured. The results of the measurement are shown in Table 2 below.

TABLE 2

| | Comparative Example 1 | | Example 1 | |
|---|---|---|---|---|
| | | Luminance | | Luminance |
| | Luminance | difference | Luminance | difference |
| | (cd/m²) | (cd/m²) | (cd/m²) | (cd/m²) |
| First active | 936 | 28 | 936 | 16 |
| area | | | | |
| Second active | 908 | | 920 | |
| area | | | | |

From the results in Table 2 above, it can be seen that the difference in luminance between the first active area and the second active area decreased from 28 cd/m² to 16 cd/m² in the case in which the electron-blocking layer of the blue light-emitting element was doped with the N-type dopant, compared to the case in which the electron-blocking layer was not doped with the N-type dopant.

As the difference in luminance between the first active area and the second active area decreases, the boundary between the first active area and the second active area is not clearly recognized.

Electroluminescent (EL) characteristics were measured by applying a forward bias DC voltage to the red, green, and blue light-emitting elements, and the results of the measurement are shown in Table 3 below. In Table 3 below, Comparative Example 2 is one in which the hole-blocking layer of the light-emitting element was not doped with the P-type dopant, and Example 2 is one in which the hole-blocking layer of the light-emitting element was doped with the P-type dopant.

TABLE 3

| | Red light- | | Green light- | | Blue light- | |
|---|---|---|---|---|---|---|
| | emitting | | emitting | | emitting | |
| | element | | element | | element | |
| | Effi- | T95 | Effi- | T95 | Effi- | T95 |
| | ciency | lifespan | ciency | lifespan | ciency | lifespan |
| | (%) | (%) | (%) | (%) | (%) | (%) |
| Comparative | 100% | 100% | 100% | 100% | 100% | 100% |
| Example 2 | | | | | | |
| Example 2 | 104% | 95% | 99% | 136% | 99% | 108% |

From the results in Table 3 above, it can be seen that the T95 lifespan increased in the case in which the hole-blocking layer of each of the green and blue light emitting elements was doped with the P-type dopant, compared to the case in which the hole-blocking layer was not doped with the P-type dopant.

It was confirmed that, in the case in which the hole-blocking layer of the red light-emitting element was doped with the P-type dopant, the efficiency increased, but the lifespan decreased.

The above-described embodiments of the present disclosure are briefly described as follows.

The display device according to embodiments of the present disclosure includes: a first active area in which a plurality of first pixels are disposed and which has a first resolution; a second active area in which a plurality of second pixels are disposed and which has a second resolution lower than the first resolution; and multiple light-emitting elements disposed in each of the plurality of first pixels and the plurality of second pixels, wherein each of the multiple light-emitting elements includes a first electrode layer, an electron-blocking layer on the first electrode layer, a light-emitting layer on the electron-blocking layer, a hole-blocking layer on the light-emitting layer, and a second electrode layer on the hole-blocking layer, wherein at least one of the electron-blocking layer or the hole-blocking layer includes a dopant, and the number of moles of the dopant in at least one of the electron-blocking layer or the hole-blocking layer located in the second active area may be greater than the number of moles of the dopant in at least one of the electron-blocking layer or the hole-blocking layer located in the first active area.

In the display device according to embodiments of the present disclosure, the electron-blocking layer includes an N-type dopant, and the number of moles of the N-type dopant in the electron-blocking layer may satisfy Equation 1 below:

$$0 \leq {e}_{P 1} < {e}_{P 2} \qquad [ Equation 1 ]$$

In Equation 1 above, e_{P1} is the number of moles of the N-type dopant in the electron-blocking layer in the first pixel, and e_{P2} is the number of moles of the N-type dopant in the electron-blocking layer in the second pixel.

In the display device according to embodiments of the present disclosure, the number of moles of the N-type dopant in the electron-blocking layer may satisfy Equation 2 below:

$$0 = {e}_{P 1} < {e}_{P 2} \qquad [ Equation 2 ]$$

In Equation 2 above, e_{P1} is the number of moles of the N-type dopant in the electron-blocking layer in the first pixel, and e_{P2} is the number of moles of the N-type dopant in the electron-blocking layer in the second pixel.

In the display device according to embodiments of the present disclosure, the number of moles of the N-type dopant in the electron-blocking layer may satisfy Equation 3 below:

$$0 \leq {e}_{P 1} < {e}_{P 2} \leq 0.5 {E}_{P 2} \qquad [ Equation 3 ]$$

In Equation 3 above, e_{P1} is the number of moles of the N-type dopant in the electron-blocking layer in the first pixel, e_{P2} is the number of moles of the N-type dopant in the electron-blocking layer in the second pixel, and E_{P2} is the number of moles of the electron-blocking layer in the second pixel.

In the display device according to embodiments of the present disclosure, the N-type dopant may be at least one of the following compounds:

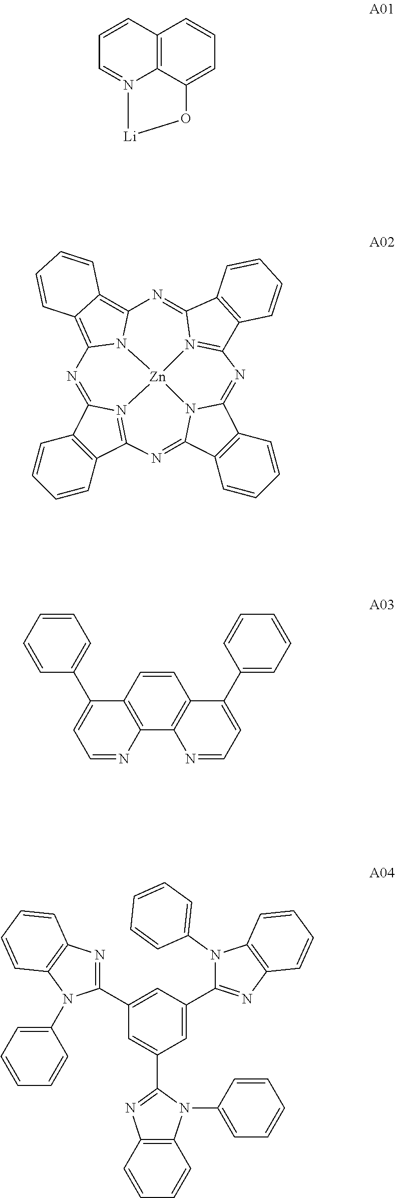

In the display device according to embodiments of the present disclosure, the hole-blocking layer may include a P-type dopant, and the number of moles of the P-type dopant in the hole-blocking layer may satisfy Equation 4 below:

$$0 \leq {h}_{P 1} < {h}_{P 2} \qquad [ Equation 4 ]$$

In Equation 4 above, h_{P1} is the number of moles of the P-type dopant in the hole-blocking layer in the first pixel, and h_{P2} is the number of moles of the P-type dopant in the hole-blocking layer in the second pixel.

In the display device according to embodiments of the present disclosure, the number of moles of the P-type dopant in the hole-blocking layer may satisfy Equation 5 below:

$$0 = {h}_{P 1} < {h}_{P 2} \qquad [ Equation 5 ]$$

In Equation 5 above, h_{P1} is the number of moles of the P-type dopant in the hole-blocking layer in the first pixel, and h_{P2} is the number of moles of the P-type dopant in the hole-blocking layer in the second pixel.

In the display device according to embodiments of the present disclosure, the P-type dopant may be at least one of the following compounds:

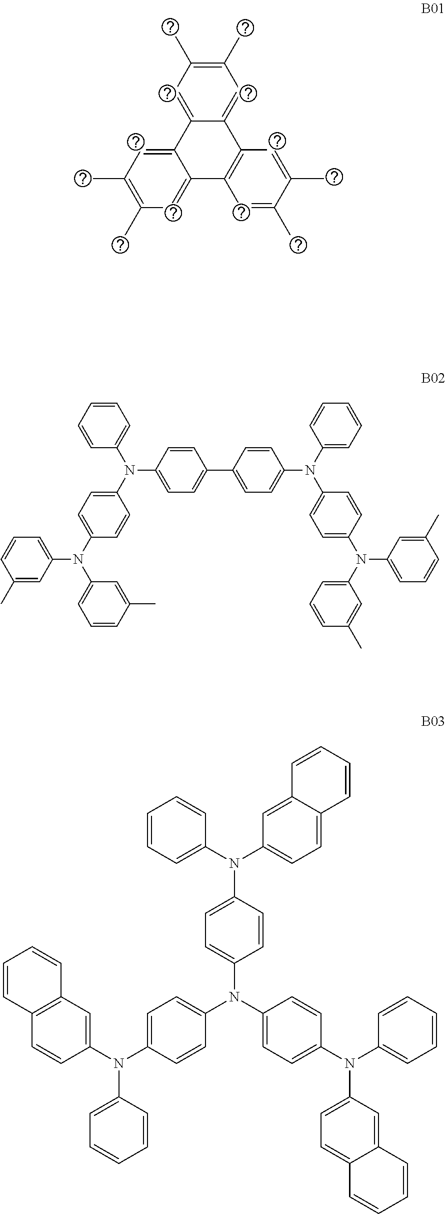

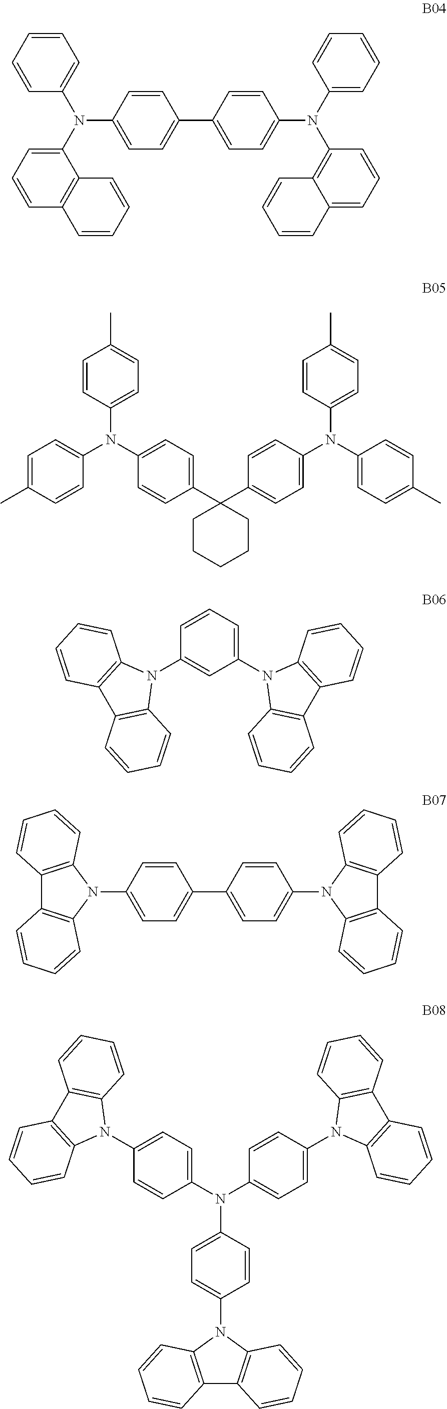

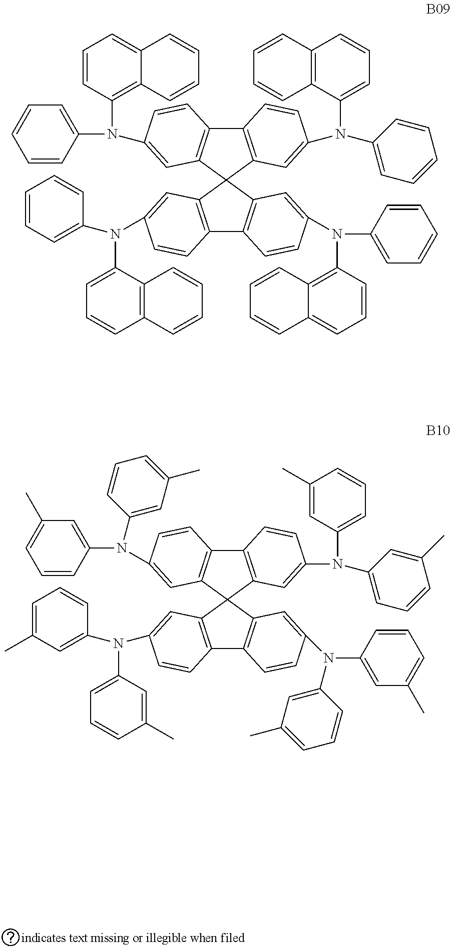

The display device according to embodiments of the present disclosure includes: a first active area in which a plurality of first pixels are disposed and which has a first resolution; a second active area in which a plurality of second pixels are disposed and which has a second resolution lower than the first resolution; and multiple light-emitting elements disposed in each of the plurality of first pixels and the plurality of second pixels, wherein each of the multiple light-emitting elements includes a first electrode layer, an electron-blocking layer on the first electrode layer, a light-emitting layer on the electron-blocking layer, and a second electrode layer on the light-emitting layer, wherein the electron-blocking layer includes a dopant, and the number of moles of the dopant in the electron-blocking layer located in the second active area may be greater than the number of moles of the dopant in the electron-blocking layer located in the first active area.

The display device according to embodiments of the present disclosure includes: a first active area in which a plurality of first pixels are disposed and which has a first resolution; a second active area in which a plurality of second pixels are disposed and which has a second resolution lower than the first resolution; and multiple light-emitting elements disposed in each of the plurality of first pixels and the plurality of second pixels, wherein each of the multiple light-emitting elements includes a first electrode layer, a light-emitting layer on the first electrode layer, a hole-blocking layer on the light-emitting layer, and a second electrode layer on the hole-blocking layer, wherein the hole-blocking layer includes a dopant, and the number of moles of the dopant in the hole-blocking layer located in the second active area may be greater than the number of moles of the dopant in the hole-blocking layer located in the first active area.

The above description has been presented to enable any person skilled in the art to make and use the technical idea of the present disclosure and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device comprising:
a first active area in which a plurality of first pixels are disposed, wherein the plurality of first pixels has a first resolution;
a second active area in which a plurality of second pixels are disposed, wherein the plurality of second pixels has a second resolution lower than the first resolution; and
multiple light-emitting elements disposed in each of the plurality of first pixels and the plurality of second pixels,
wherein each of the multiple light-emitting elements comprises:
a first electrode layer;
an electron-blocking layer on the first electrode layer;
a light-emitting layer on the electron-blocking layer;
a hole-blocking layer on the light-emitting layer; and
a second electrode layer on the hole-blocking layer,
wherein at least one of the electron-blocking layer or the hole-blocking layer comprises a dopant, and a number of moles of the dopant in at least one of the electron-blocking layer or the hole-blocking layer located in a second pixel of the second active area is greater than a number of moles of the dopant in at least one of the electron-blocking layer or the hole-blocking layer located in a first pixel of the first active area.

2. The display device of claim 1, wherein the electron-blocking layer comprises an N-type dopant, and the number of moles of the N-type dopant in the electron-blocking layer satisfies Equation 1 below:
$$0 \leq {e}_{P 1} < {e}_{P 2} \qquad [ Equation 1 ]$$
wherein e_{P1} is the number of moles of the N-type dopant in the electron-blocking layer in the first pixel, and e_{P2} is the number of moles of the N-type dopant in the electron-blocking layer in the second pixel.

3. The display device of claim 2, wherein the number of moles of the N-type dopant in the electron-blocking layer satisfies equation 2 below:
$$0 = {e}_{P 1} < {e}_{P 2} \qquad [ Equation 2 ]$$
wherein e_{P1} is the number of moles of the N-type dopant in the electron-blocking layer in the first pixel, and e_{P2} is the number of moles of the N-type dopant in the electron-blocking layer in the second pixel.

4. The display device of claim 2, wherein the number of moles of the N-type dopant in the electron-blocking layer satisfies Equation 3 below:
$$0 \leq {e}_{P 1} < {e}_{P 2} \leq 0.5 {E}_{P 2} \qquad [ Equation 3 ]$$
wherein e_{P1} is the number of moles of the N-type dopant in the electron-blocking layer in the first pixel, e_{P2} is the number of moles of the N-type dopant in the electron-blocking layer in the second pixel, and E_{P2} is the number of moles of the electron-blocking layer in the second pixel.

5. The display device of claim 2, wherein the N-type dopant is at least one of the following compounds:

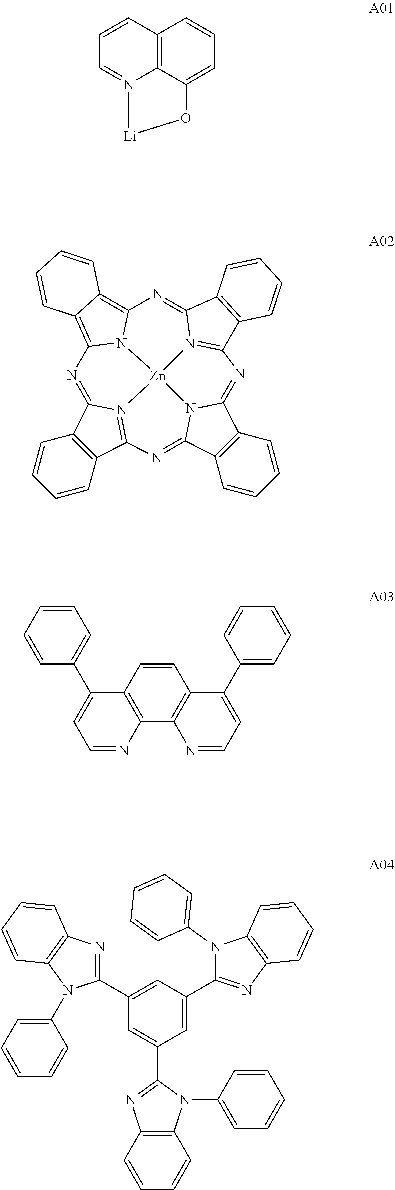

6. The display device of claim 1, wherein the hole-blocking layer comprises a P-type dopant, and the number of moles of the P-type dopant in the hole-blocking layer satisfies Equation 4 below:
$$0 \leq {h}_{P 1} < {h}_{P 2} \qquad [ Equation 4 ]$$
wherein h_{P1} is the number of moles of the P-type dopant in the hole-blocking layer in the first pixel, and h_{P2} is the number of moles of the P-type dopant in the hole-blocking layer in the second pixel.

7. The display device of claim 6, wherein the number of moles of the P-type dopant in the hole-blocking layer satisfies Equation 5 below:
$$0 = {h}_{P 1} < {h}_{P 2} \qquad [ Equation 5 ]$$
wherein h_{P1} is the number of moles of the P-type dopant in the hole-blocking layer in the first pixel, and h_{P2} is the number of moles of the P-type dopant in the hole-blocking layer in the second pixel.

8. The display device of claim 6, wherein the P-type dopant is at least one of the following compounds:

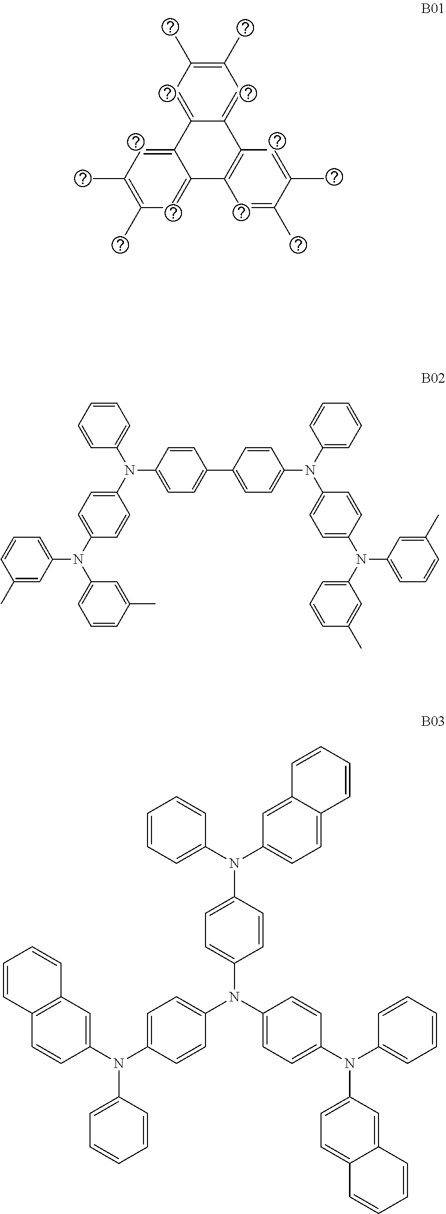

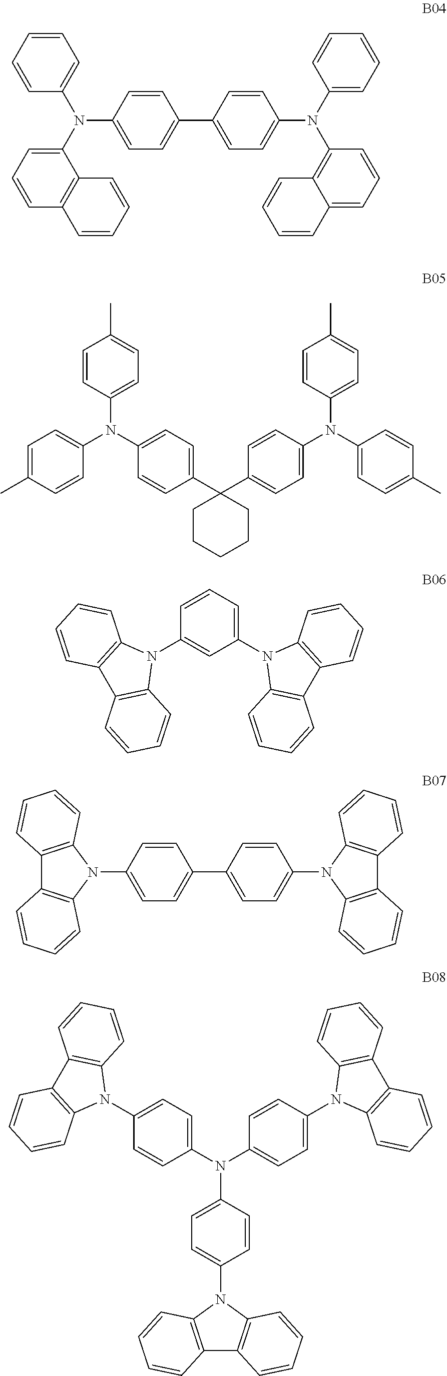

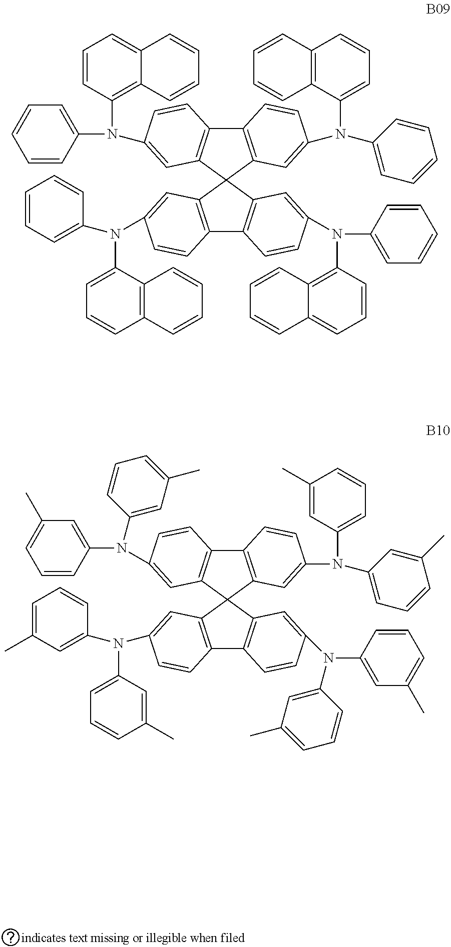

9. A display device comprising:
a substrate;
a plurality of first pixels disposed in a first active area of the substrate, wherein the plurality of first pixels has a first resolution, wherein at least a first pixel includes a light-emitting element including a first electron-blocking layer and a light-emitting layer on the first electron-blocking layer;
a plurality of second pixels disposed in a second active area of the substrate, wherein the plurality of second pixels has a second resolution lower than the first resolution, wherein at least a second pixel includes a light-emitting element including a second electron-blocking layer and a light-emitting layer on the second electron-blocking layer; and
wherein at least the second electron-blocking layer comprises a dopant, and an amount of the dopant in the second electron-blocking layer located in the second active area is greater than an amount of the dopant in the first electron-blocking layer located in the first active area.

10. The display device of claim 9, wherein the amount of the dopant in the first electron-blocking layer is a first number of moles of the dopant, wherein the amount of dopant in the second electron-blocking layer is a second number of moles of the dopant.

11. The display device of claim 10, wherein the first electron-blocking layer does not include the dopant.

12. The display device of claim 9, wherein the dopant is a N-type dopant, wherein the dopant is at least one of the following compounds:

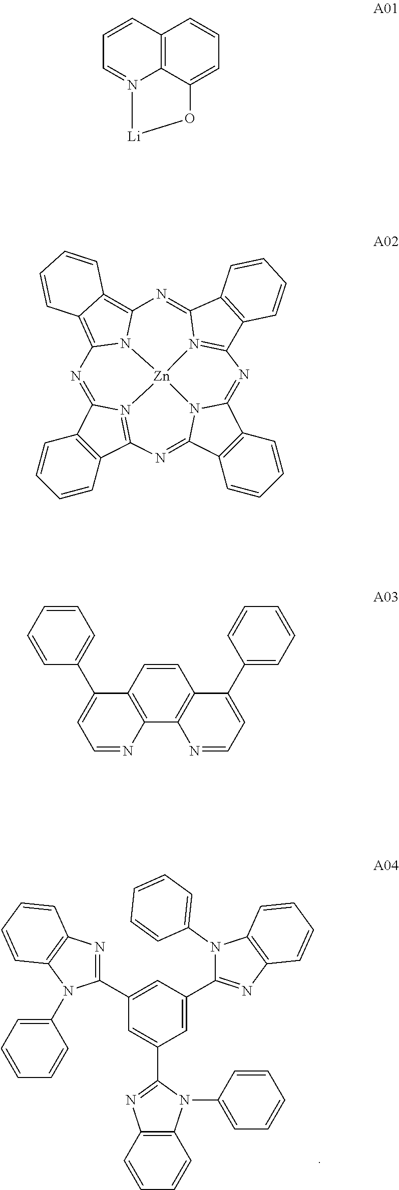

13. The display device of claim 9, wherein the second pixel includes:
a first electrode;
a common hole transport layer on the first electrode;
a red light-emitting auxiliary layer on a first portion of the common hole transport layer;
a green light-emitting auxiliary layer on a second portion of the common hole transport layer;
the second electron-blocking layer on the red light-emitting auxiliary layer, the green light-emitting auxiliary layer, and a third portion of the common hole transport layer;
the light-emitting layer;
an electron transport layer on the light-emitting layer; and
a second electrode on the electron transport layer.

14. The display device of claim 9, further comprising a lens disposed below the plurality of second pixels.

15. A display device comprising:
a substrate;
a plurality of first pixels disposed in a first active area of the substrate, wherein the plurality of first pixels has a first resolution, wherein at least a first pixel includes a light-emitting element including a light-emitting layer and a first hole-blocking layer on the light-emitting layer;
a plurality of second pixels disposed in a second active area of the substrate, wherein the plurality of red pixels has a second resolution lower than the first resolution, wherein at least a second pixel includes a light-emitting element including a light-emitting layer and a second hole-blocking layer on the light-emitting layer; and
wherein at least the second hole-blocking layer comprises a dopant, and an amount of the dopant in the second hole-blocking layer located in the second active area is greater than an amount of the dopant in the first hole-blocking layer located in the first active area.

16. The display device of claim 15, wherein the amount of the dopant in the first hole-blocking layer is a first number of moles of the dopant, wherein the amount of dopant in the second hole-blocking layer is a second number of moles of the dopant.

17. The display device of claim 15, wherein the first hole-blocking layer does not include the dopant.

18. The display device of claim 15, wherein the dopant is a P-type dopant, wherein the dopant is at least one of the following compounds:

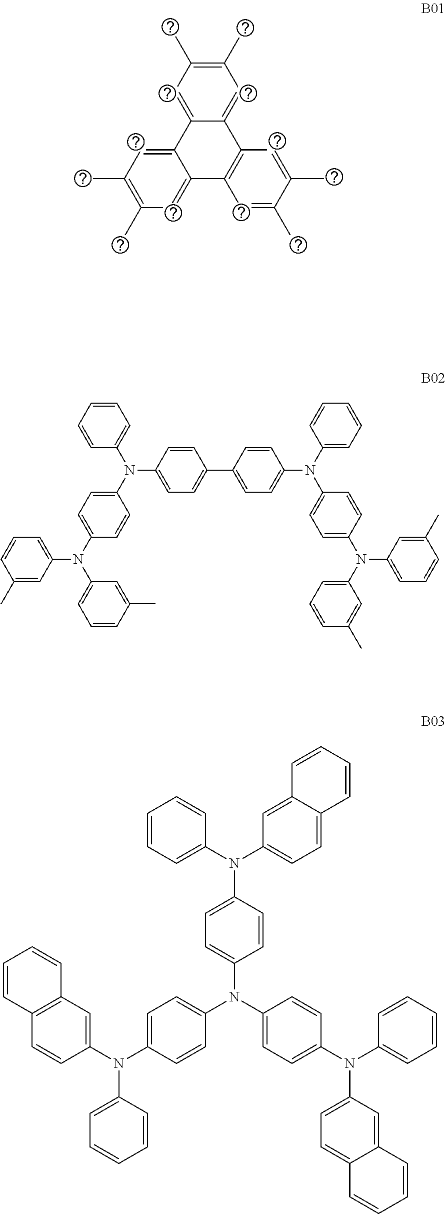

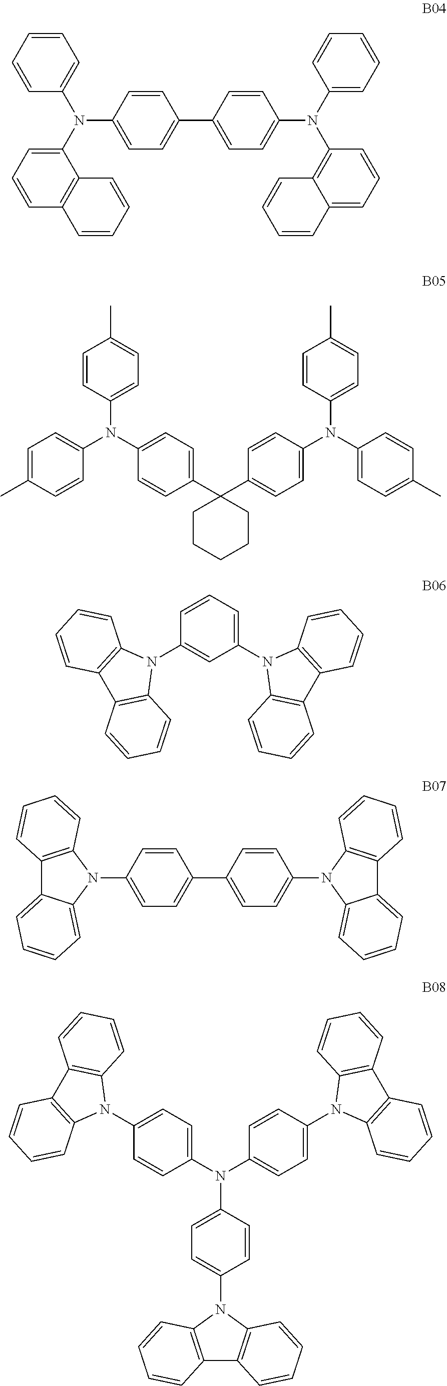

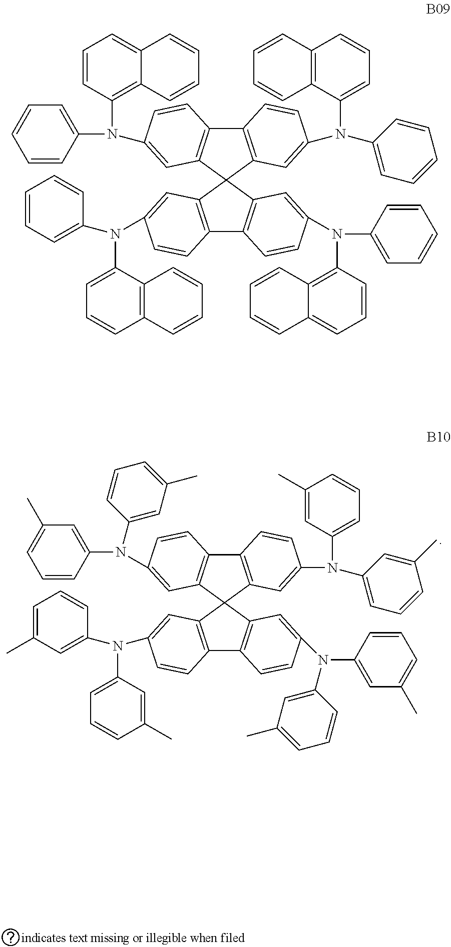

19. The display device of claim 15, wherein the second pixel includes:
a first electrode;
a common hole transport layer on the first electrode;
a red light-emitting auxiliary layer on a first portion of the common hole transport layer;
a green light-emitting auxiliary layer on a second portion of the common hole transport layer;
the light-emitting layer;
the second hole-blocking layer on the light-emitting layer;
an electron transport layer on the second hole-blocking layer; and
a second electrode on the electron transport layer.

20. The display device of claim 15, further comprising a lens disposed below the plurality of second pixels.
